(19) United States
(12) Patent Application Publication
(10) Pub. No.: US 2026/0005179 A1
(43) Pub. Date: Jan. 1, 2026

(54) SEMICONDUCTOR DEVICE AND METHOD FOR PRODUCING SEMICONDUCTOR DEVICE

(71) Applicant: Rohm Co., Ltd., Kyoto-shi (JP)

(72) Inventor: Satoshi KAGEYAMA, Kyoto-shi (JP)

(21) Appl. No.: 19/316,319

(22) Filed: Sep. 2, 2025

Related U.S. Application Data
(63) Continuation of application No. PCT/JP2024/006253, filed on Feb. 21, 2024.

(30) Foreign Application Priority Data
Mar. 7, 2023 (JP) 2023-034700

(51) Int. Cl. H01L 23/00; H01L 23/31; H01L 25/03

(52) U.S. Cl. CPC H01L 24/24; H01L 23/3135; H01L 24/16; H01L 24/19; H01L 25/03; H01L 2224/16227; H01L 2224/19; H01L 2224/24137; H01L 2224/24146; H01L 2224/244

(57) ABSTRACT

A semiconductor device includes a wiring layer, a first semiconductor element, and a first sealing resin. The wiring layer includes a first wiring and a second wiring. The first semiconductor element includes a first electrode and a second electrode disposed opposite to each other in a first direction. The first electrode is electrically bonded to the first wiring. The first sealing resin covers the first semiconductor element. The first sealing resin includes a first surface and a second surface facing away from each other in the first direction. The first surface is closer to the first electrode than to the second electrode. The second wiring is exposed from each of the first surface and the second surface. As viewed in the first direction, the second wiring is spaced apart from the first semiconductor element.

### TECHNICAL FIELD

The present disclosure relates to a semiconductor device and a method for producing/manufacturing the same.

### BACKGROUND ART

A semiconductor device for motor drive control includes a plurality of switching elements, such as MOSFETs, and an IC for driving the switching elements. JP-A-2017-34079 discloses an example of a semiconductor device including a plurality of switching elements and an IC (see FIG. 11 of JP-A-2017-34079). The semiconductor device is used for controlling a brushless DC motor.

The semiconductor device disclosed in JP-A-2017-34079 includes six switching elements for converting DC power into three-phase AC power. These switching elements are arranged along one direction (the x direction in FIG. 11 of JP-A-2017-34079), resulting in the semiconductor device having a strip shape elongated along that direction. Consequently, the leads that are electrically connected to the IC are also arranged along that direction. This contributes to the relatively large size of the semiconductor device. In response to recent demands for more compact semiconductor devices, further size reduction of devices such as the one disclosed in JP-A-2017-34079 is desired.

### BRIEF DESCRIPTION OF THE DRAWINGS

FIG. 1 is a plan view of a semiconductor device according to a first embodiment of the present disclosure.

FIG. 2 is a plan view corresponding to FIG. 1, in which a second semiconductor element, a third semiconductor element, and a second sealing resin are depicted as transparent.

FIG. 3 is a plan view corresponding to FIG. 2, in which portions of the wiring layers and first sealing resin are omitted.

FIG. 4 is a bottom view of the semiconductor device shown in FIG. 1.

FIG. 5 is a sectional view taken along line V-V in FIG. 2.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is an enlarged view showing a portion of FIG. 6.

FIG. 10 is a sectional view illustrating a manufacturing step of the semiconductor device shown in FIG. 1.

FIG. 11 is a sectional view illustrating a manufacturing step of the semiconductor device shown in FIG. 1.

FIG. 12 is a sectional view illustrating a manufacturing step of the semiconductor device shown in FIG. 1.

FIG. 13 is a sectional view illustrating a manufacturing step of the semiconductor device shown in FIG. 1.

FIG. 14 is a sectional view illustrating a manufacturing step of the semiconductor device shown in FIG. 1.

FIG. 15 is a sectional view illustrating a manufacturing step of the semiconductor device shown in FIG. 1.

FIG. 16 is a sectional view illustrating a manufacturing step of the semiconductor device shown in FIG. 1.

FIG. 17 is a sectional view illustrating a manufacturing step of the semiconductor device shown in FIG. 1.

FIG. 18 is a sectional view illustrating a manufacturing step of the semiconductor device shown in FIG. 1.

FIG. 19 is a sectional view illustrating a manufacturing step of the semiconductor device shown in FIG. 1.

FIG. 20 is a sectional view illustrating a manufacturing step of the semiconductor device shown in FIG. 1.

FIG. 21 is a sectional view illustrating a manufacturing step of the semiconductor device shown in FIG. 1.

FIG. 22 is a sectional view illustrating a manufacturing step of the semiconductor device shown in FIG. 1.

FIG. 23 is a sectional view illustrating a manufacturing step of the semiconductor device shown in FIG. 1.

FIG. 24 is a sectional view illustrating a manufacturing step of the semiconductor device shown in FIG. 1.

FIG. 25 is a sectional view illustrating a manufacturing step of the semiconductor device shown in FIG. 1.

FIG. 26 is a sectional view illustrating a manufacturing step of the semiconductor device shown in FIG. 1.

FIG. 27 is a sectional view illustrating a manufacturing step of the semiconductor device shown in FIG. 1.

FIG. 28 is a plan view of a semiconductor device according to a second embodiment of the present disclosure.

FIG. 29 is a bottom view of the semiconductor device shown in FIG. 28.

FIG. 30 is a sectional view taken along line XXX-XXX in FIG. 28.

FIG. 31 is a sectional view taken along line XXXI-XXXI in FIG. 28.

### DETAILED DESCRIPTION OF EMBODIMENTS

The flowing describes embodiments of the present disclosure, with reference to the attached drawings.

### First Embodiment

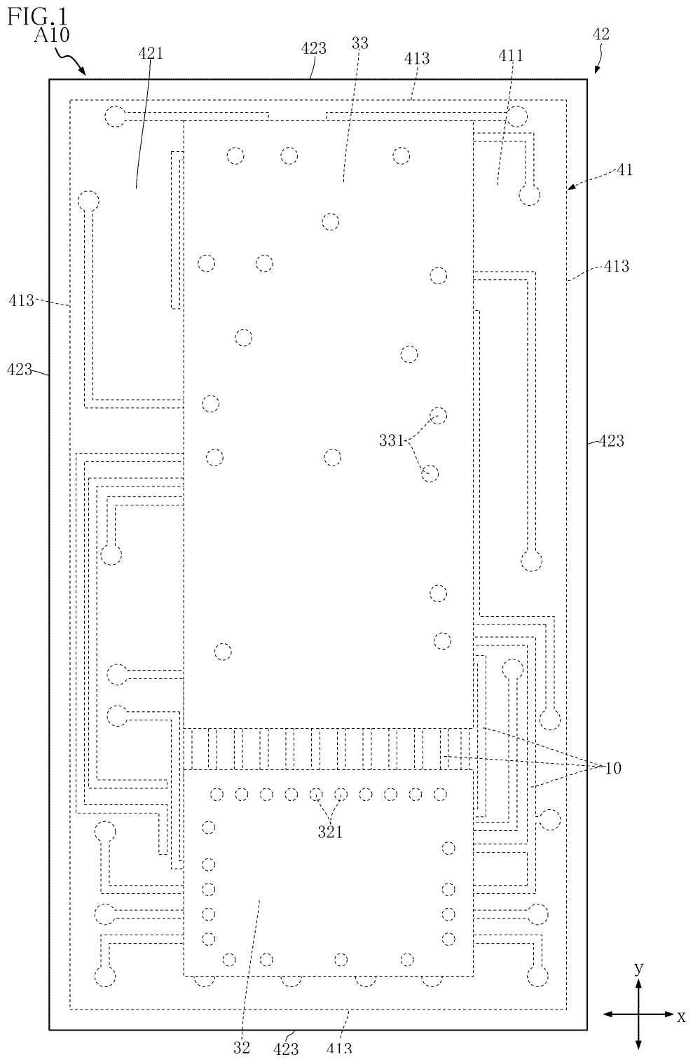

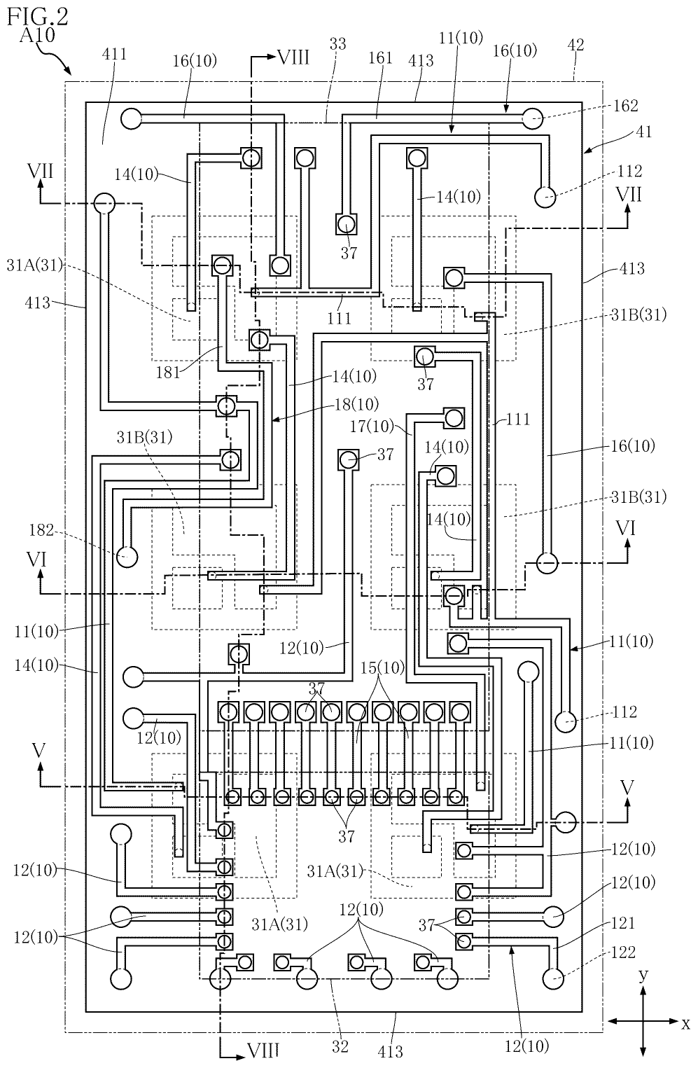

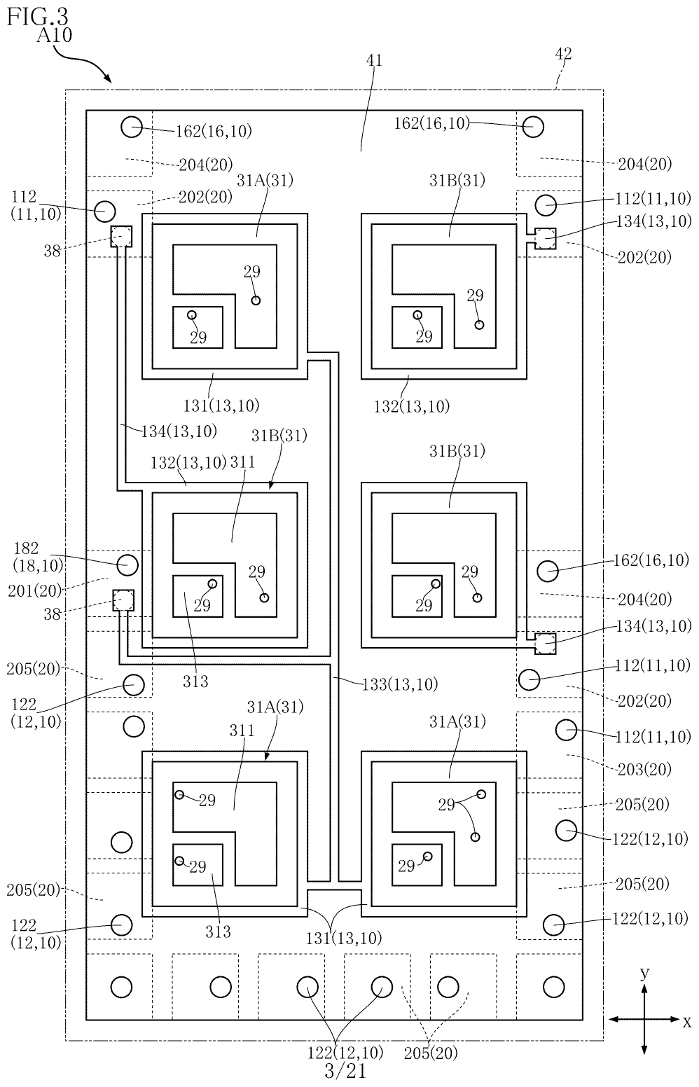

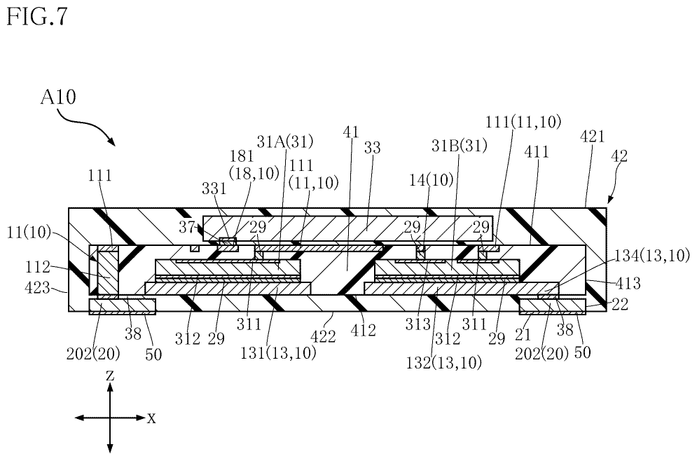

With reference to FIGS. 1 to 9, the following describes a semiconductor device A10 according to a first embodiment of the present disclosure. The semiconductor device A10 includes a plurality of wiring layers 10, a plurality of terminals 20, a plurality of first semiconductor elements 31, a second semiconductor element 32, a third semiconductor element 33, a first bonding layer 37, a second bonding layer 38, a first sealing resin 41, a second sealing resin 42, and a plurality of protective layers 50. The semiconductor device A10 is a resin-packaged device for surface mounting on a wiring board. For case of understanding, FIG. 2 depicts the second semiconductor element 32, the third semiconductor element 33, and the second sealing resin 42 as transparent. In FIG. 2, the outlines of the second semiconductor element 32, the third semiconductor element 33, and the second sealing resin 42 are represented by imaginary lines (dash-double-dot lines). For ease of understanding, FIG. 3 omits some of the wiring layers 10 and a portion of the first sealing resin 41 that are shown in FIG. 2. In FIG. 3, the outline of the second sealing resin 42 is represented by imaginary lines.

For convenience in the description of the semiconductor device A10, the normal direction to a later-described first surface 411 of the first sealing resin 41 is referred to as a “first direction z”, for example. A direction perpendicular to the first direction z is referred to as a “second direction x”. The direction perpendicular to the first direction z and the second direction x is referred to as a “third direction y”. As shown in FIG. 1, the semiconductor device A10 is rectangular as viewed in the first direction z.

The semiconductor device A10 receives DC power from an external source and converts the DC power into three-phase AC current by using the first semiconductor elements 31. The semiconductor device A10 is used for controlling a brushless DC motor, for example.

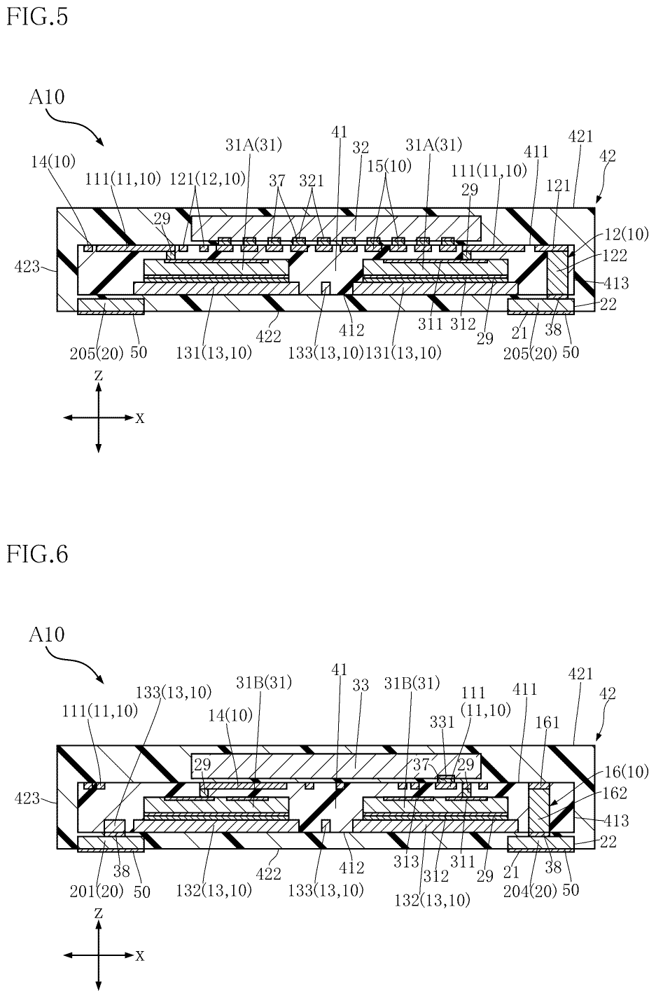

As shown in FIGS. 5 to 8, the first sealing resin 41 covers the first semiconductor elements 31. The first scaling resin 41 is electrically insulating. The first sealing resin 41 is made of a material containing a black epoxy resin, for example. As shown in FIGS. 5 to 8, the first scaling resin 41 has a first surface 411, a second surface 412, and a plurality of first side surfaces 413. The first surface 411 and the second surface 412 face away from each other in the first direction z. Each first side surface 413 faces in a direction perpendicular to the first direction z. Each first side surface 413 is connected to the first surface 411 and the second surface 412. In the semiconductor device A10, the plurality of first side surfaces 413 include two first side surfaces 413 facing in the second direction x, and two first side surfaces 413 facing in the third direction y.

As shown in FIGS. 5 to 8, the second scaling resin 42 covers the second semiconductor element 32 and the third semiconductor element 33. The first surface 411, the second surface 412, and the first side surfaces 413 are each covered with the second sealing resin 42. The second scaling resin 42 is electrically insulating. The second scaling resin 42 is made of a material containing a black epoxy resin, for example. The second sealing resin 42 has a top surface 421, a bottom surface 422, and a plurality of second side surfaces 423. The top surface 421 faces the same side as the first surface 411 of the first scaling resin 41 in the first direction z. The bottom surface 422 faces away from the top surface 421 in the first direction z. Each second side surface 423 is connected to the top surface 421 and the bottom surface 422. In the semiconductor device A10, the plurality of second side surfaces 423 include two second side surfaces 423 facing in the second direction x and two second side surfaces 423 facing in the third direction y.

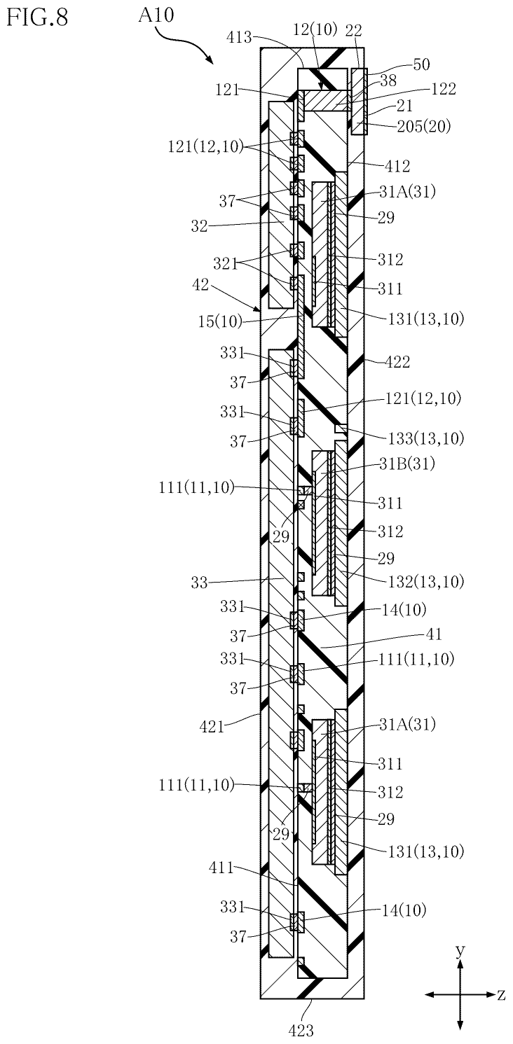

As shown in FIG. 9, the second surface 412 of the first scaling resin 41 has a surface roughness that is higher than the surface roughness of the top surface 421 of the second scaling resin 42. The first surface 411 of the first scaling resin 41 and the bottom surface 422 of the second sealing resin 42 each have a surface roughness that is higher than the surface roughness of the top surface 421 and is lower than the surface roughness of the second surface 412.

As shown in FIGS. 5 to 8, each first semiconductor element 31 is electrically bonded to a third wiring 13, which is one of the wiring layers 10 and will be described later. The first semiconductor elements 31 are all identical. For example, the first semiconductor elements 31 are MOSFETs (metal-oxide-semiconductor field-effect transistors). In other examples, the first semiconductor elements 31 may be field-effect transistors, including MISFETs (metal-insulator-semiconductor field-effect transistors), or bipolar transistors, such as IGBTs (insulated gate bipolar transistors). The description of the semiconductor device A10 is directed to the first semiconductor elements 31 that are n-channel, vertical MOSFETs. The first semiconductor elements 31 include a compound semiconductor substrate. The compound semiconductor substrate contains silicon carbide (SiC) in composition. The first semiconductor elements 31 include three first elements 31A and three second elements 31B. In the semiconductor device A10, the three first elements 31A and the three second elements 31B form a half-bridge circuit. The three first elements 31A form an upper arm circuit of the half-bridge circuit, whereas the three second elements 31B form a lower arm circuit of the half-bridge circuit.

As shown in FIGS. 3 and 6, each first semiconductor element 31 includes a first electrode 311, a second electrode 312, and a gate electrode 313.

As shown in FIG. 6, the first electrode 311 and the second electrode 312 are disposed opposite to each other in the first direction z. The first surface 411 of the first sealing resin 41 is closer to the first electrode 311 than to the second electrode 312. The first electrode 311 conducts electric current corresponding to the power modulated by the first semiconductor element 31. That is, the first electrode 311 is the source of the first semiconductor element 31. The second electrode 312 conducts electric current corresponding to the power before modulation by the first semiconductor element 31. That is, the second electrode 312 is the drain of the first semiconductor element 31. The second electrode 312 of each first semiconductor element 31 is electrically bonded to the third wiring 13, which is one of the wiring layers 10 and will be described later, via a conductive bonding layer 29. The conductive bonding layer 29 contains nickel (Ni), tin (Sn), and silver (Ag). Alternatively, the conductive bonding layer 29 may contain nickel, tin, and antimony (Sb).

As shown in FIG. 6, the gate electrode 313 is on the same side as the first electrode 311 in the first direction z. The gate electrode 313 is supplied with a gate voltage for controlling the first semiconductor element 31. As shown in FIG. 3, the gate electrode 313 has a smaller area than the first electrode 311 as viewed in the first direction z.

As shown in FIGS. 5 to 8, the plurality of terminals 20 are embedded in the second sealing resin 42. The terminals 20 face the second surface 412 of the first sealing resin 41. The terminals 20, together with the wiring layers 10, form conduction paths that connect the first semiconductor elements 31, the second semiconductor element 32, and the third semiconductor element 33 to a wiring board on which the semiconductor device A10 is mounted. Each terminal 20 is electrically connected to one of the wiring layers 10. The terminals 20 contain copper (Cu).

As shown in FIGS. 5 to 8, each terminal 20 has a mounting surface 21 and an end surface 22. The mounting surface 21 faces the same side as the bottom surface 422 of the second sealing resin 42 in the first direction z. The mounting surface 21 of each terminal 20 is exposed from the bottom surface 422. The end surface 22 faces in a direction perpendicular to the first direction z. In the semiconductor device A10, the end surface 22 of each terminal 20 is covered with the second sealing resin 42.

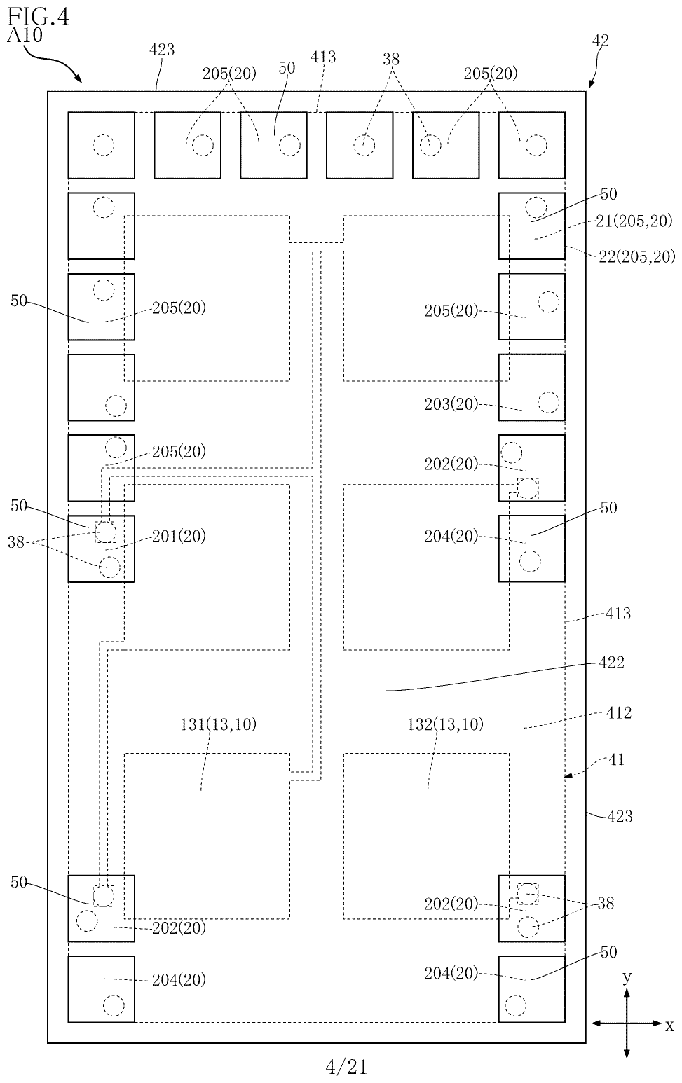

As shown in FIG. 4, the plurality of terminals 20 include a first power terminal 201, three second electrode terminals 202, a third power terminal 203, three boot terminal 204, and a plurality of control terminals 205. These terminals will be described after the description of the wiring layers 10, the second semiconductor element 32, the third semiconductor element 33, and the protective layers 50.

As shown in FIGS. 5 to 8, the wiring layers 10 are embedded in the first sealing resin 41. Each wiring layer 10 is exposed from at least one of the first surface 411 and the second surface 412 of the first sealing resin 41. The wiring layers 10 contain copper. As shown in FIGS. 2 and 3, the plurality of wiring layers 10 include four first wirings 11, a plurality of second wirings 12, a third wiring 13, a plurality of fourth wirings 14, a plurality of fifth wirings 15, three sixth wirings 16, a seventh wiring 17, and an eighth wiring 18. All of the wiring layers 10 other than the third wiring 13 are in contact with the second sealing resin 42.

As shown in FIG. 2, the four first wirings 11 each have a wiring section 111 and a pillar section 112. The wiring section 111 is exposed from the first surface 411 of the first sealing resin 41. The pillar section 112 is physically and electrically connected to the wiring section 111. With respect to the wiring section 111, the pillar section 112 is located on the side that the second surface 412 of the first sealing resin 41 faces in the first direction z. The pillar section 112 is exposed from the second surface 412. Thus, each of the four first wirings 11 is exposed from both the first surface 411 and the second surface 412.

The first electrode 311 of each of the three first elements 31A is electrically bonded to the wiring section 111 of one of three first wirings 11, out of the four first wirings 11, via a conductive bonding layer 29. The pillar section 112 of each of the three first wirings 11 is electrically bonded to one of the three second electrode terminals 202 via a second bonding layer 38. The second bonding layers 38 contain nickel, tin, and antimony. The first electrode 311 of each of the three second elements 31B is electrically bonded to the wiring section 111 of the remaining one of the four first wirings 11 via a conductive bonding layer 29. The pillar section 112 of the one first wiring 11 is electrically bonded to the third power terminal 203 via a second bonding layer 38.

As shown in FIG. 2, at least one of the second wirings 12 is spaced apart from each first semiconductor element 31 as viewed in the first direction z. At least one of the second wirings 12 includes a portion located between the first semiconductor elements 31 and either of the first side surfaces 413 of the first scaling resin 41. Each second wiring 12 has a wiring section 121 and a pillar section 122. The wiring section 121 is exposed from the first surface 411 of the first sealing resin 41. The pillar section 122 is physically and electrically connected to the wiring section 121. With respect to the wiring section 121, the pillar section 122 is located on the side that the second surface 412 of the first sealing resin 41 faces in the first direction z. The pillar section 122 is exposed from the second surface 412. Thus, each second wiring 12 is exposed from both the first surface 411 and the second surface 412. The pillar section 122 of each second wiring 12 is electrically bonded to a control terminal 205 via a second bonding layer 38.

As shown in FIGS. 5 to 8, the third wiring 13 is exposed from the second surface 412 of the first sealing resin 41. As shown in FIG. 3, the third wiring 13 has three first pad sections 131, three second pad sections 132, a first wiring section 133, and three second wiring sections 134. The second electrode 312 of each of the three first elements 31A is electrically bonded to one of the three first pad sections 131 via a conductive bonding layer 29. The second electrode 312 of each of the three second elements 31B is electrically bonded to one of the three second pad sections 132 via a conductive bonding layer 29. The first wiring section 133 is physically and electrically connected to the three first pad sections 131. The first wiring section 133 is electrically bonded to the first power terminal 201 via a second bonding layer 38. Each of the three second wiring sections 134 is physically and electrically connected to one of the three second pad sections 132. Each of the three second wiring sections 134 is electrically bonded to one of the three second electrode terminals 202 via a second bonding layer 38. The dimension of the third wiring 13 in the first direction z is larger than the dimension of each of the four first wirings 11 in the first direction z.

As shown in FIG. 2, each fourth wiring 14 is exposed from the first surface 411 of the first scaling resin 41. Each fourth wiring 14 is electrically bonded to the gate electrode 313 of one of the first semiconductor elements 31 via a conductive bonding layer 29.

As shown in FIGS. 2 and 8, each fifth wiring 15 is exposed from the first surface 411 of the first sealing resin 41. The fifth wirings 15 are next to each other in the second direction x.

As shown in FIG. 2, each of the three sixth wirings 16 has a wiring section 161 and a pillar section 162. The wiring section 161 is exposed from the first surface 411 of the first sealing resin 41. The pillar section 162 is physically and electrically connected to the wiring section 161. With respect to the wiring section 161, the pillar section 162 is located on the side that the second surface 412 of the first sealing resin 41 faces in the first direction z. The pillar section 162 is exposed from the second surface 412. Thus, each of the three sixth wirings 16 is exposed from both the first surface 411 and the second surface 412. The pillar section 162 of each of the three sixth wirings 16 is electrically bonded to one of the three boot terminals 204 via a second bonding layer 38.

As shown in FIG. 2, the seventh wiring 17 is exposed from the first surface 411 of the first scaling resin 41. The seventh wiring 17 is electrically bonded to the first electrode 311 of one of the three second elements 31B via a conductive bonding layer 29.

As shown in FIG. 2, the eighth wiring 18 has a wiring section 181 and a pillar section 182. The wiring section 181 is exposed from the first surface 411 of the first sealing resin 41. The pillar section 182 is physically and electrically connected to the wiring section 181. With respect to the wiring section 181, the pillar section 182 is located on the side that the second surface 412 of the first sealing resin 41 faces in the first direction z. The pillar section 182 is exposed from the second surface 412. Thus, the eighth wiring 18 is exposed from both the first surface 411 and the second surface 412. The eighth wiring 18 is electrically bonded to the first power terminal 201 via a second bonding layer 38.

As shown in FIGS. 5 and 8, the second semiconductor element 32 faces the first surface 411 of the first scaling resin 41. As shown in FIG. 2, the second semiconductor element 32 overlaps with one or more of the first semiconductor elements 31 as viewed in the first direction z. The second semiconductor element 32 is electrically connected to the third semiconductor element 33. The second semiconductor element 32 is an IC that controls the third semiconductor element 33. The second semiconductor element 32 has a plurality of electrodes 321 facing a plurality of wiring layers 10. Each electrode 321 is electrically bonded to the wiring section 121 of a second wiring 12 or a fifth wiring 15 via a first bonding layer 37. The first bonding layers 37 contain nickel and tin. The melting point of the first bonding layers 37 is different from the melting point of the second bonding layers 38. In the semiconductor device A10, the melting point of the first bonding layers 37 is lower than that of the second bonding layers 38.

As shown in FIGS. 6 to 8, the third semiconductor element 33 faces the first surface 411 of the first sealing resin 41. As shown in FIG. 2, the third semiconductor element 33 overlaps with one or more of the first semiconductor elements 31 as viewed in the first direction z. The third semiconductor element 33 is located next to the second semiconductor element 32 in the third direction y. The dimension of the third semiconductor element 33 in the third direction y is larger than the dimension of the second semiconductor element 32 in the third direction y. The third semiconductor element 33 is electrically connected to the first electrode 311 and the gate electrode 313 of each first semiconductor element 31. The third semiconductor element 33 is a gate driver that applies a gate voltage to the gate electrode 313 of each first semiconductor element 31. The third semiconductor element 33 has a plurality of electrodes 331 facing a plurality of wiring layers 10. The electrodes 331 include those electrically connected to the wiring sections 111 of the four first wirings 11, the wiring sections 121 of two of the second wirings 12, the fourth wirings 14, and the fifth wirings 15, each via a first bonding layer 37. The rest of the first electrodes 311 are electrically bonded to the wiring sections 161 of the sixth wirings 16, the seventh wiring 17, and the wiring section 181 of the eighth wiring 18, each via a first bonding layer 37.

As shown in FIGS. 4 to 8, the protective layers 50 are exposed to the outside of the semiconductor device A10. Each protective layer 50 covers the mounting surface 21 of a terminal 20 exposed from the bottom surface 422 of the second scaling resin 42.

The protective layers 50 are conductors. The semiconductor device A10 is attached to a wiring board by electrically bonding the protective layers 50 to the wiring board via solder. Each protective layer 50 includes a plurality of metal layers. The metal layers include a nickel layer and a gold layer that are stacked in this order, starting from the one closer to the bottom surface 422 of the second scaling resin 42. Alternatively, the metal layers include a nickel layer, a palladium (Pd) layer, and a gold layer stacked in this order, starting from the one closer to the bottom surface 422. That is, each protective layer 50 contains gold.

The following describes the specific terminals 20, namely, the first power terminal 201, the three second electrode terminals 202, the third power terminal 203, the three boot terminals 204, and the control terminals 205.

The first power terminal 201 is electrically connected to the respective second electrodes 312 of the three first elements 31A via the third wiring 13 and also to the third semiconductor element 33 via the eighth wiring 18. The third power terminal 203 is electrically connected, via one of the four first wirings 11, to the respective second electrodes 312 of the three second element 31B and also to the third semiconductor element 33. The first power terminal 201 and the third power terminal 203 receive DC power to be converted by the first semiconductor elements 31. The first power terminal 201 is a positive terminal (P terminal), whereas the second electrode terminal 202 is a negative terminal (N terminal).

The three second electrode terminals 202 are electrically connected to the respective first electrodes 311 of the three first elements 31A via three of the four first wirings 11. The three second electrode terminals 202 are electrically connected to the respective second electrodes 312 of the three second elements 31B via the third wiring 13. The three second electrode terminals 202 are electrically connected also to a plurality of capacitors that are external to the semiconductor device A10. Those capacitors form part of a bootstrap circuit for the semiconductor device A10. Each of the three second electrode terminals 202 outputs one of the U-phase, V-phase, or W phase components of the three-phase AC power modulated by the first semiconductor elements 31. The three-phase AC power is used to drive a motor that is external to the semiconductor device A10.

The three boot terminals 204 are electrically connected to the third semiconductor element 33 via the three sixth wirings 16. The three boot terminals 204 are electrically connected also to a plurality of capacitors that are external to the semiconductor device A10. When the third semiconductor element 33 applies a gate voltage to the gate electrode 313 of one of the three first elements 31A, current flows into the third semiconductor element 33 from one of the capacitors via one of the three boot terminals 204.

The control terminals 205 are electrically connected to the second semiconductor element 32 via the second wirings 12. One or more of the control terminals 205 are electrically connected also to the third semiconductor element 33 via the second wirings 12. One of the control terminals 205 is used to input the power for driving the second semiconductor element 32 and the third semiconductor element 33. One of the control terminals 205 is used to input an electrical signal into the second semiconductor element 32. One of the control terminals 205 outputs an electrical signal generated by the second semiconductor element 32.

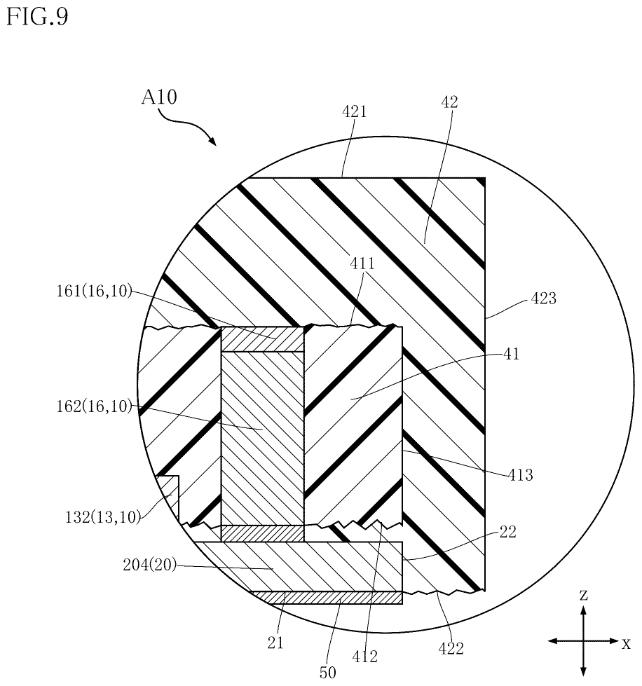

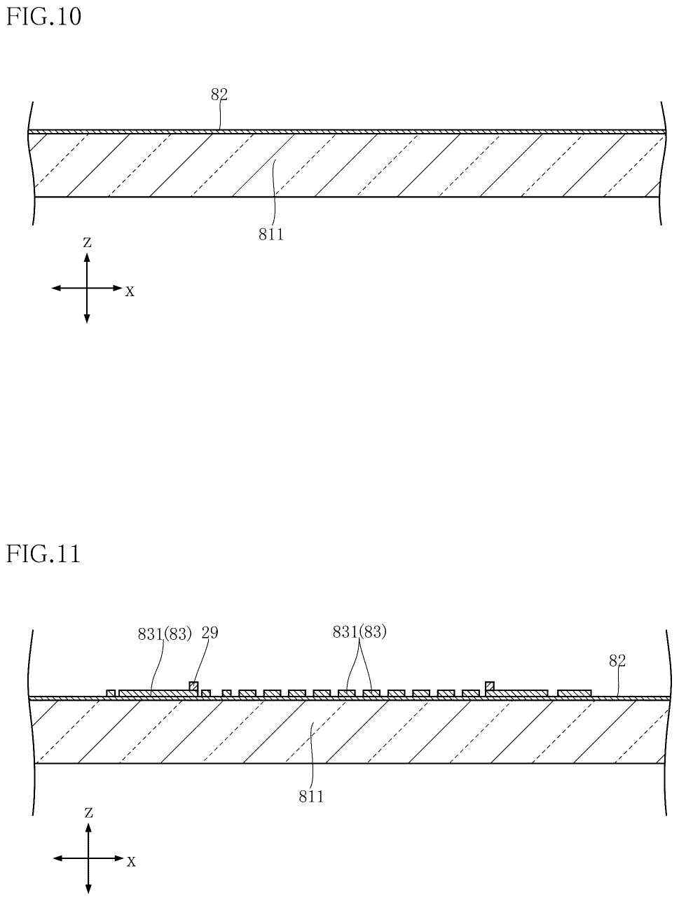

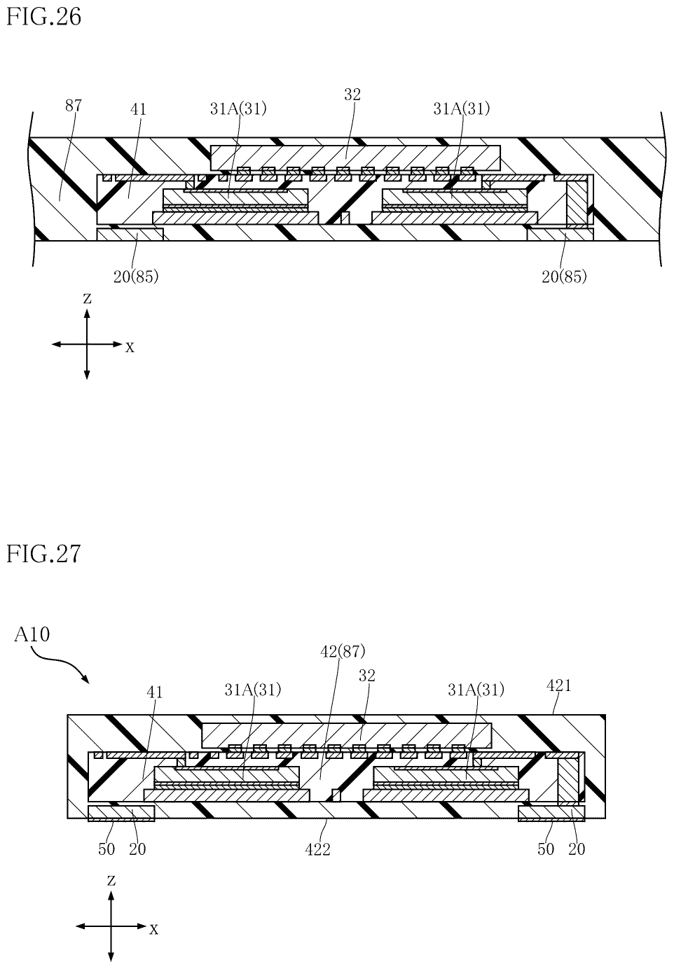

With reference to FIGS. 10 to 27, the following describes an example of a method for manufacturing the semiconductor device A10. Note that FIGS. 10 to 27 each show a section taken along the same line as the section shown in FIG. 5.

First, as shown in FIG. 10, the method includes preparing a first substrate 811, and forming an intermediate layer 82 that covers a first side of the first substrate 811 in the first direction z. The first substrate 811 is a silicon wafer. The intermediate layer 82 is in contact with the first substrate 811 and consists of thin metal films: a titanium film and a copper film stacked on the titanium film. The intermediate layer 82 is formed by sputtering the respective thin metal films.

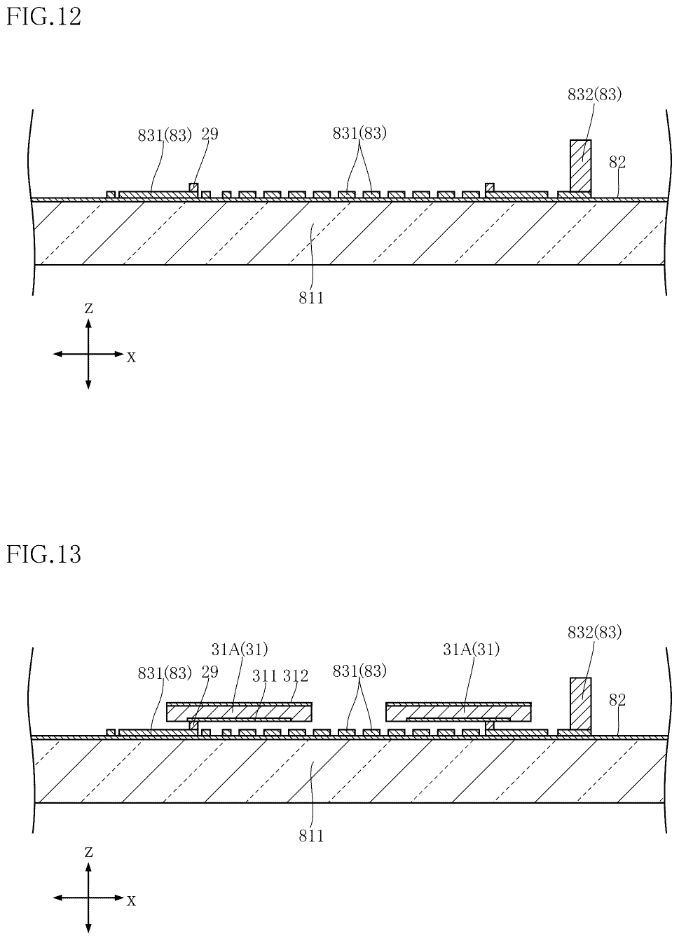

Subsequently, as shown in FIGS. 11 to 12, the method includes forming a first conductive layer 83 and a conductive bonding layer 29 on the intermediate layer 82 that is formed on the first substrate 811. The first conductive layer 83 includes wiring sections 831 and pillar sections 832. The first conductive layer 83 corresponds to the wiring layers 10 of the semiconductor device A10, other than the third wiring 13.

First, as shown in FIG. 11, the wiring sections 831 of the first conductive layer 83 are formed on the intermediate layer 82. To form the wiring sections 831, the intermediate layer 82 is patterned by lithography. Then, electroplating is performed using the intermediate layer 82 as a conductive path to deposit the wiring sections 831. Then, the mask layer used for the lithographic patterning is removed. In this way, the wiring sections 831 are formed.

Subsequently, as shown in FIG. 11, a conductive bonding layer 29 is formed on relevant wiring sections 831 of the first conductive layer 83. To form the conductive bonding layer 29, the intermediate layer 82 and the wiring sections 831 are patterned by lithography. Then, electroplating is performed using the intermediate layer 82 and the wiring sections 831 as a conductive path to deposit the conductive bonding layer 29. Then, the mask layer used for the lithographic patterning is removed. In this way, the conductive bonding layer 29 is formed.

Finally, as shown in FIG. 12, pillar sections 832 protruding from the wiring sections 831 of the first conductive layer 83 in the first direction z are formed. To form the pillar sections 832, the intermediate layer 82, the wiring sections 831 of the first conductive layer 83, and the conductive bonding layer 29 are patterned by lithography. Then, electroplating is performed using the intermediate layer 82 and the wiring sections 831 as a conductive path to deposit the pillar sections 832. Then, the mask layer used for the lithographic patterning is removed. As a result of the above, the first conductive layer 83 and the conductive bonding layer 29 are formed.

Subsequently, as shown in FIG. 13, the method includes flip-chip bonding of the first semiconductor elements 31, in which their first electrodes 311 and the gate electrodes 313 are electrically bonded to the wiring sections 831 of the first conductive layer 83 via the conductive bonding layer 29.

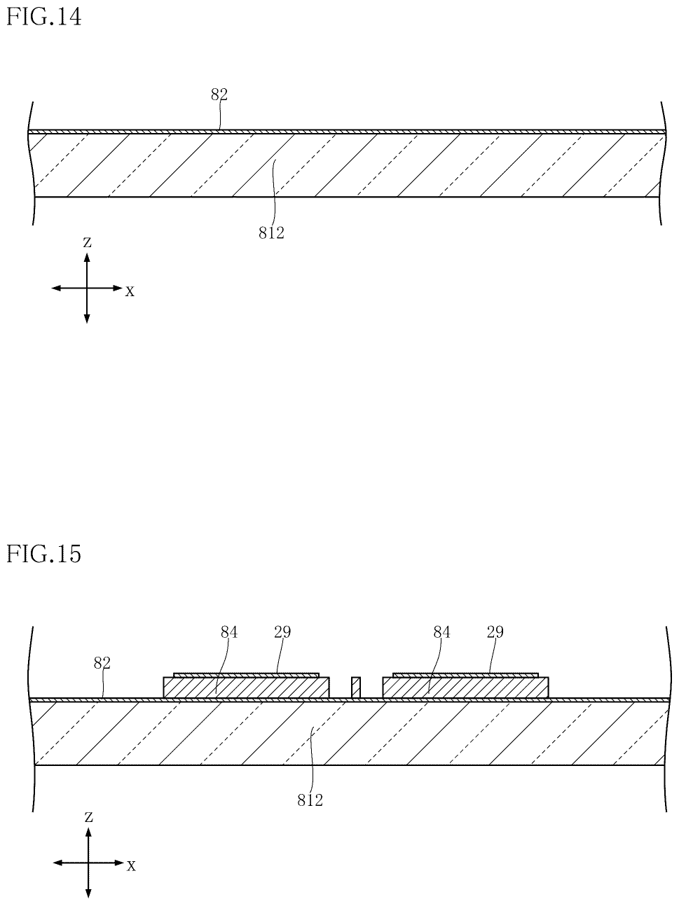

Subsequently, as shown in FIG. 14, the method includes preparing a second substrate 812, and forming an intermediate layer 82 that covers a first side of the second substrate 812 in the first direction z. The second substrate 812 is a silicon wafer. The intermediate layer 82 is in contact with the second substrate 812 and consists of thin metal films: a titanium film and a copper film stacked on the titanium film. The intermediate layer 82 are formed by sputtering the respective thin metal films.

Subsequently, as shown in FIG. 15, the method includes forming a second conductive layer 84 and a conductive bonding layer 29 on the intermediate layer 82 that is formed on the second substrate 812. The second conductive layer 84 corresponds to the third wiring 13, which is one of the wiring layers 10 of the semiconductor device A10.

Specifically, as shown in FIG. 15, the second conductive layer 84 is formed on the intermediate layer 82. To form the second conductive layer 84, the intermediate layer 82 is patterned by lithography. Then, electroplating is performed using the intermediate layer 82 as a conductive path to deposit the second conductive layer 84. Then, the mask layer used for the lithographic patterning is removed. In this way, the second conductive layer 84 is formed.

Subsequently, as shown in FIG. 15, a conductive bonding layer 29 is formed on the second conductive layer 84. To form the conductive bonding layer 29, the intermediate layer 82 and the second conductive layer 84 are patterned by lithography. Then, electroplating is performed using the intermediate layer 82 and the second conductive layer 84 as a conductive path to deposit the conductive bonding layer 29. Then, the mask layer used for the lithographic patterning is removed. As a result of the above, the second conductive layer 84 and the conductive bonding layer 29 are formed.

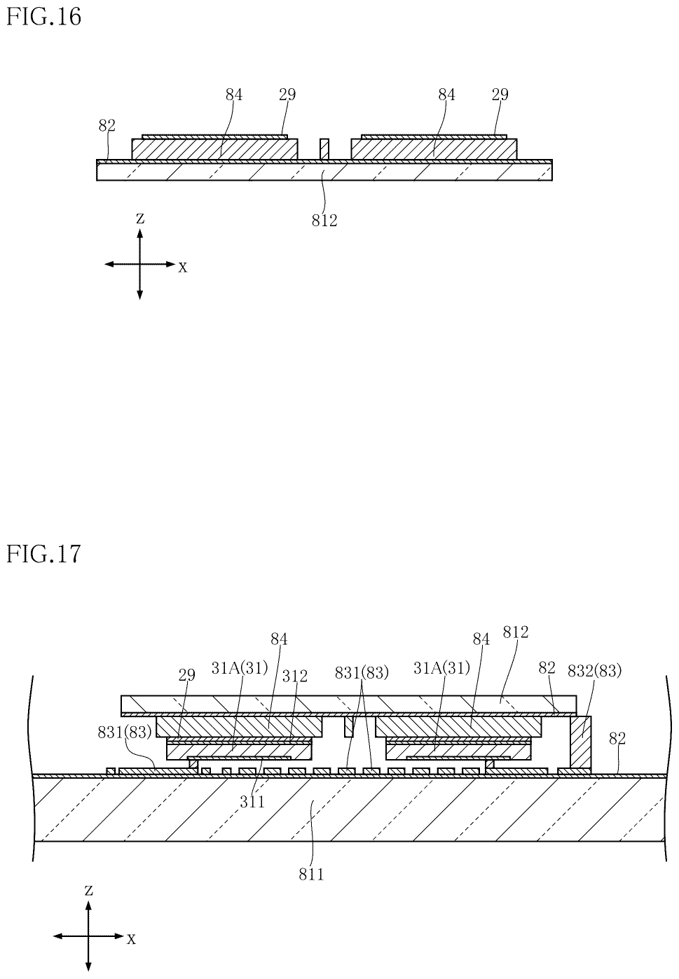

Subsequently, as shown in FIG. 16, the method includes removing a portion of the second substrate 812 by grinding the side opposite the intermediate layer 82 in the first direction z, and then dividing the second substrate 812 into individual dies by blade dicing. The second conductive layer 84 on the second substrate 812 of each die will form the third wiring 13 of one semiconductor device A10.

Subsequently, as shown in FIG. 17, the method includes inverting the second substrate 812 of the individual die by rotation about an axis perpendicular to the first direction z, and then electrically bonding the second conductive layer 84 to the second electrodes 312 of the respective first semiconductor elements 31 via the conductive bonding layer 29. The electrical bonding is performed by reflowing.

Subsequently, as shown in FIG. 18, the method includes forming a first resin layer 86 that covers the first conductive layer 83, the second conductive layer 84, and the first semiconductor elements 31. The first resin layer 86 corresponds to the first sealing resin 41 of the semiconductor device A10. The first sealing resin 41 is formed by transfer molding. Here, the first resin layer 86 is formed to cover the entire second substrate 812.

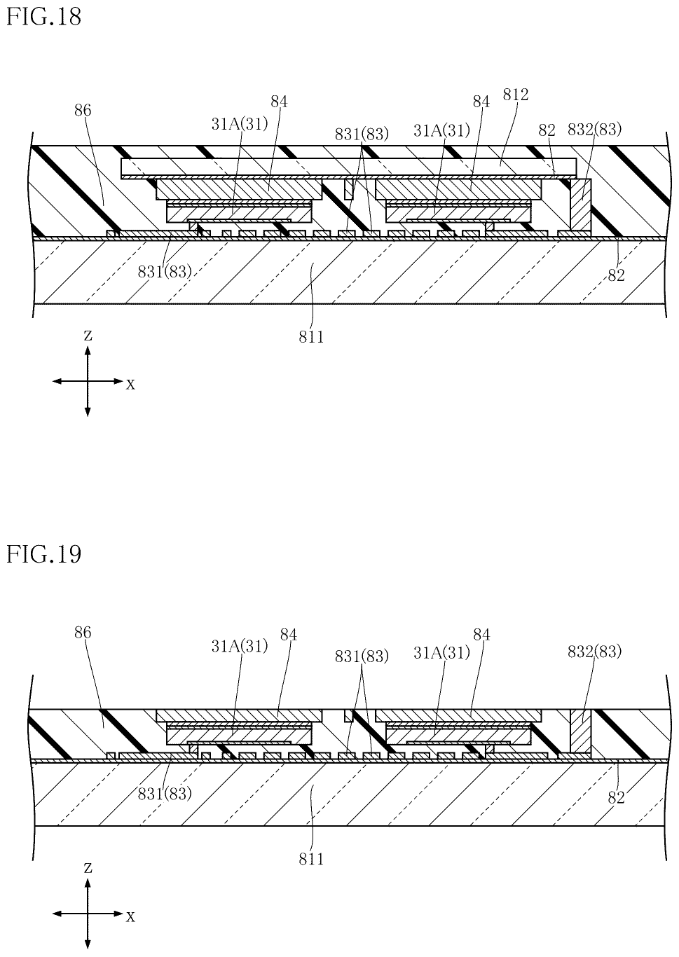

Subsequently, as shown in FIG. 19, the method includes removing a portion of the first resin layer 86 by grinding a first side of the first resin layer 86 in the first direction z. Here, the second substrate 812, the intermediate layer 82 that is formed on the second substrate 812, and a portion of the second conductive layer 84 are removed along with the portion of the first resin layer 86.

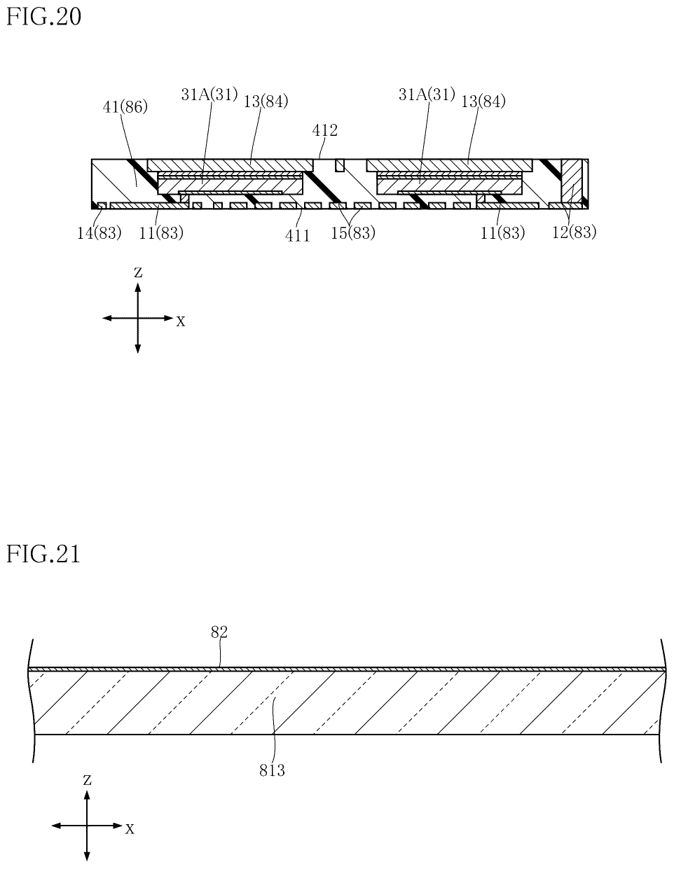

Subsequently, as shown in FIG. 20, the method includes removing the first substrate 811 and the intermediate layer 82 that is formed on the first substrate 811 by grinding, and then dividing the first resin layer 86 into individual dies by blade dicing. The first resin layer 86 of each individual die will form the first sealing resin 41. Additionally, the first conductive layer 83 and the second conductive layers 84 will form a plurality of wiring layers 10 each having a portion exposed from the first sealing resin 41.

Subsequently, as shown in FIG. 21, the method includes preparing a third substrate 813, and forming an intermediate layer 82 that covers a first side of the third substrate 813 in the first direction z. The third substrate 813 is a silicon wafer. The intermediate layer 82 is in contact with the third substrate 813 and consists of thin metal films: a titanium film and a copper film stacked on the titanium film. The intermediate layer 82 are formed by sputtering the respective thin metal films.

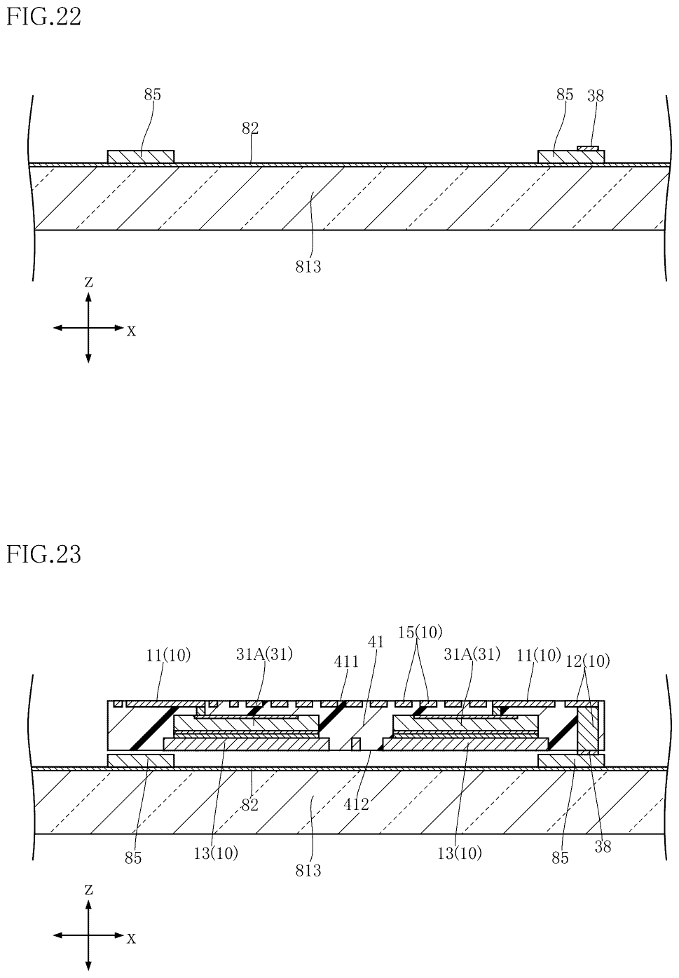

Subsequently, as shown in FIG. 22, the method includes forming a third conductive layer 85 and a second bonding layer 38 on the intermediate layer 82 that is formed on the third substrate 813. The third conductive layer 85 corresponds to the terminals 20 of the semiconductor device A10.

Specifically, as shown in FIG. 22, the third conductive layer 85 is formed on the intermediate layer 82. To form the third conductive layer 85, the intermediate layer 82 is patterned by lithography. Then, electroplating is performed using the intermediate layer 82 as a conductive path to deposit the third conductive layer 85. Then, the mask layer used for the lithographic patterning is removed. In this way, the third conductive layer 85 is formed.

Subsequently, as shown in FIG. 22, the second bonding layer 38 is formed on the third conductive layer 85. To form the second bonding layer 38, the intermediate layer 82 and the third conductive layer 85 are patterned by lithography. Then, electroplating is performed using the intermediate layer 82 and the third conductive layer 85 as a conductive path to deposit the second bonding layer 38. Then, the mask layer used for the lithographic patterning is removed. As a result of the above, the third conductive layer 85 and the second bonding layer 38 are formed.

Subsequently, as shown in FIG. 23, the method includes electrically bonding portions of the wiring layers 10 exposed from the second surface 412 of the first sealing resin 41 to the third conductive layer 85 via the second bonding layer 38. The electrical bonding is formed by reflowing.

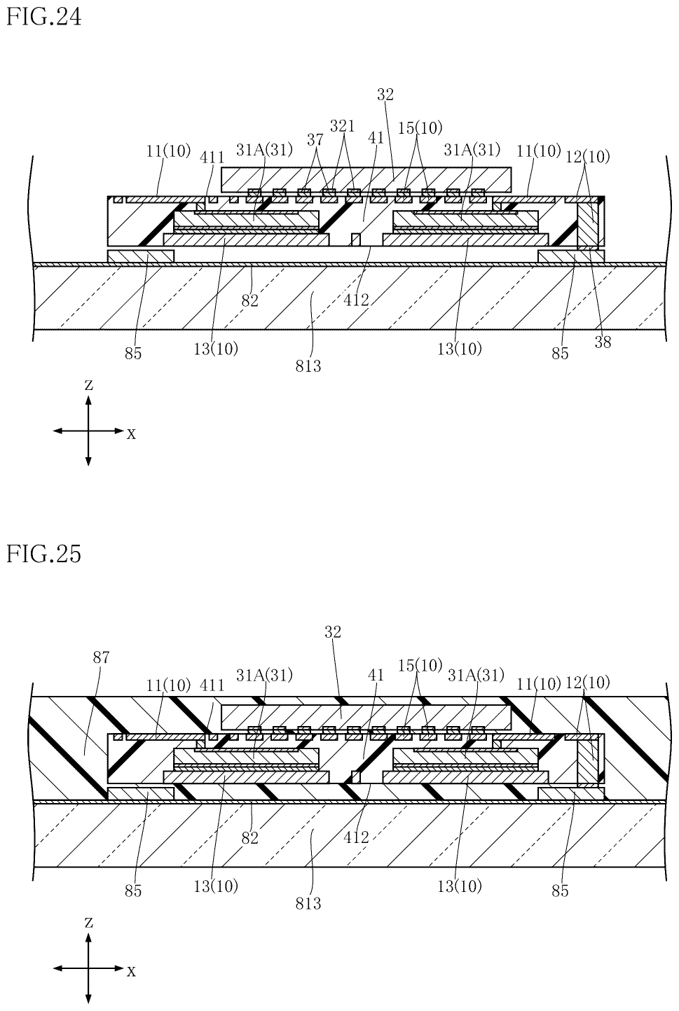

Subsequently, as shown in FIG. 24, the method includes flip-chip bonding of the second semiconductor element 32 and the third semiconductor element 33, in which the electrodes 321 and the electrodes 331 are electrically bonded to the portions of the wiring layers 10 exposed from the first surface 411 of the first sealing resin 41 via the first bonding layer 37. Note that the melting point of the first bonding layer 37 is set to be lower than that of the second bonding layer 38.

Subsequently, as shown in FIG. 25, the method includes forming a second resin layer 87 that covers the second semiconductor element 32 and the third semiconductor element 33. The second resin layer 87 corresponds to the second sealing resin 42 of the semiconductor device A10. The second sealing resin 42 is formed by transfer molding. Here, the second resin layer 87 is formed to cover the entire third conductive layer 85 and the entire first sealing resin 41.

Subsequently, as shown in FIG. 26, the method includes removing the third substrate 813 and the intermediate layer 82 that is formed on the third substrate 813 by grinding. In this way, the third conductive layer 85 is formed into a plurality of terminals 20 each having a portion exposed from the second resin layer 87.

Finally, the method includes forming a plurality of protective layers 50 that covers the exposed portions of the respective terminals 20, and then dividing the second resin layer 87 into individual dies by blade dicing. The second resin layer 87 of each individual die will form the second sealing resin 42. The protective layers 50 are formed by electroless plating. Through the steps described above, the semiconductor device A10 is completed.

The following describes effects of the semiconductor device A10.

A semiconductor device A10 includes: a wiring layer 10 that includes a first wiring 11 and a second wiring 12; a first semiconductor element 31 that includes a first electrode 311 and a second electrode 312, the first electrode 311 being electrically bonded to the first wiring 11; and a first sealing resin 41 that covers the first semiconductor element 31. The first sealing resin 41 includes a first surface 411 and a second surface 412. The first surface 411 is closer to the first electrode 311 than to the second electrode 312. The second wiring 12 is exposed from each of the first surface 411 and the second surface 412. As viewed in the first direction z, the second wiring 12 is spaced apart from the first semiconductor element 31. This configuration allows an IC that controls the first semiconductor element 31 to be mounted on the first semiconductor element 31, such that the IC overlaps with the portion of the second wiring 12 exposed from the first surface 411 as viewed in the first direction z. In addition, the portion of the second wiring 12 exposed from the second surface 412 can be used to mount the semiconductor device A10 onto a wiring board. This contributes to reducing the dimension of the semiconductor device A10 in a direction perpendicular to the first direction z. This configuration therefore enables the semiconductor device A10 to be more compact.

The wiring layer 10 includes a third wiring 13 exposed from the second surface 412 of the first scaling resin 41. The second electrode 312 of the first semiconductor element 31 is electrically bonded to the third wiring 13. This configuration facilitates the step shown in FIG. 19 of the process of manufacturing the semiconductor device A10, by preventing grinding of the second electrode 312 during the removal of a portion of the first resin layer 86 by grinding.

The semiconductor device A10 further includes: a second semiconductor element 32 electrically bonded to the second wiring 12; and a second sealing resin 42 covering the second semiconductor element 32. The second scaling resin 42 includes a top surface 421. The second surface 412 of the first sealing resin 41 has a surface roughness that is higher than the surface roughness of the top surface 421. This configuration is achieved as a result of the step shown in FIG. 19 of the process of manufacturing the semiconductor device A10. Specifically, this configuration results from the removal of a portion of the first resin layer 86 by grinding to minimize the first scaling resin 41 in the first direction z. In this way, the dimension of the semiconductor device A10 in the first direction z can be reduced while avoiding grinding of the second electrode 312 of the first semiconductor element 31.

The higher surface roughness of the second surface 412 of the first scaling resin 41, compared to the top surface 421 of the second scaling resin 42, also contributes to an anchoring effect that improves the adhesion of the second surface 412 to the second scaling resin 42. This consequently improves the adhesion of the second sealing resin 42 to the first sealing resin 41.

The semiconductor device A10 further includes a plurality of terminals 20 embedded in the second sealing resin 42. Each terminal 20 is electrically bonded to one of the second wiring 12, the third wiring 13, and the pillar section 112 of the first wiring 11. Each terminal 20 is exposed from the bottom surface 422 of the second sealing resin 42. The semiconductor device A10 of this configuration further includes a protective layer 50 that covers the portion of a terminal 20 exposed from the bottom surface 422. The protective layer 50 is a conductor that contains gold. The protective layer 50 serves to improve the wettability of molten solder during the mounting of the semiconductor device A10 onto a wiring board. This helps to prevent a reduction of the bonding area of the protective layer 50 with the solder.

The semiconductor device A10 further includes: a first bonding layer 37 electrically bonding the second wiring 12 and the second semiconductor element 32; and a second bonding layer 38 electrically bonding each terminal 20 to one of the second wiring 12, the third wiring 13, and the pillar section 112 of the first wiring 11. The second bonding layer 38 has a melting point different from that of the first bonding layer 37. This configuration facilitates the step shown in FIG. 24 of the process of manufacturing the semiconductor device A10. Specifically, when the second semiconductor element 32 is electrically bonded to the second wiring 12, the second bonding layer 38 that electrically bonds the third conductive layer 85 (the element including the plurality of terminals 20) to, for example, the third wiring 13 will not melt. This prevents displacement of the first sealing resin 41 relative to the terminals 20.

### Second Embodiment

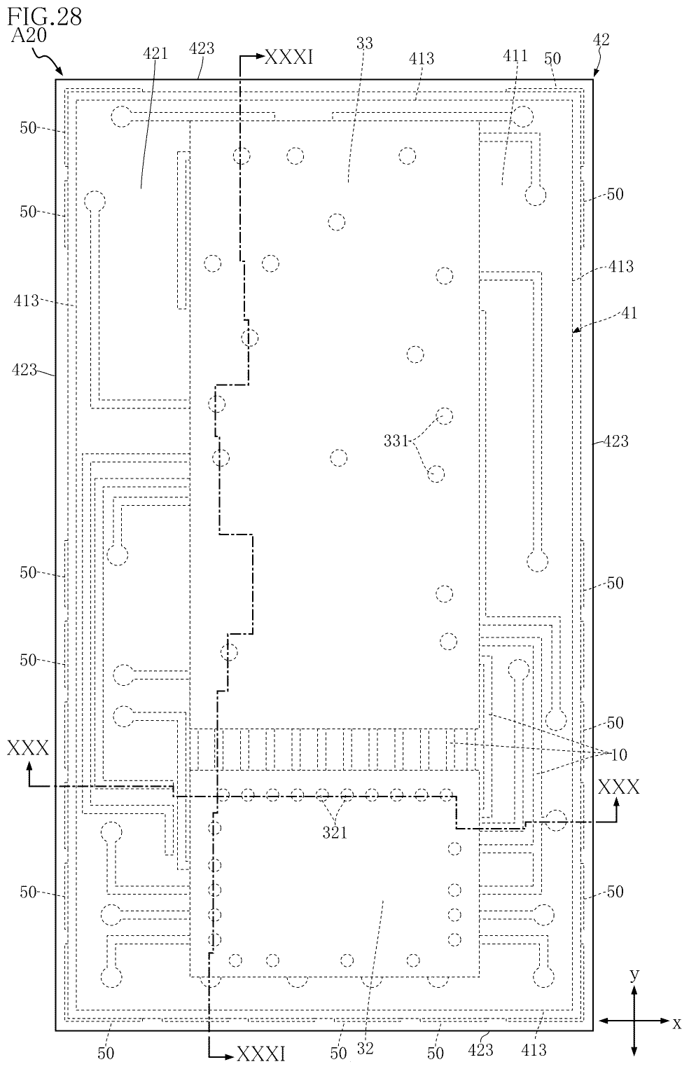

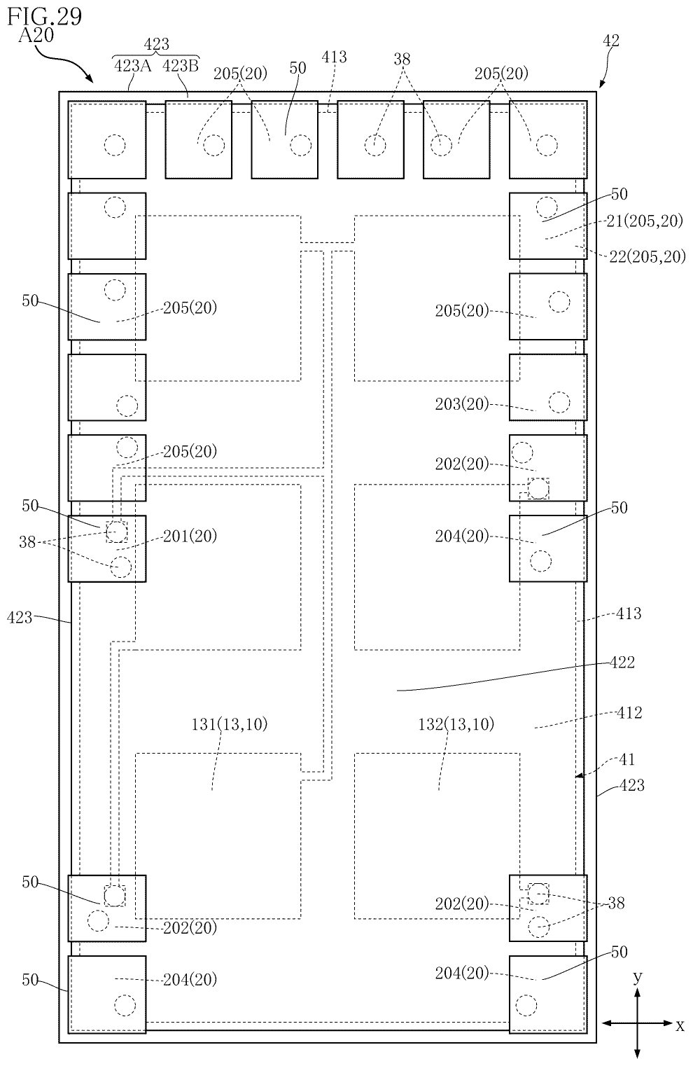

With reference to FIGS. 28 to 31, the following describes a semiconductor device A20 according to a second embodiment of the present disclosure. In these figures, elements that are identical or similar to those of the semiconductor device A10 described above are indicated by the same reference numerals, and redundant descriptions are omitted.

The semiconductor device A20 differs from the semiconductor device A10 in the configurations of the terminals 20, the second sealing resin 42, and the protective layers 50.

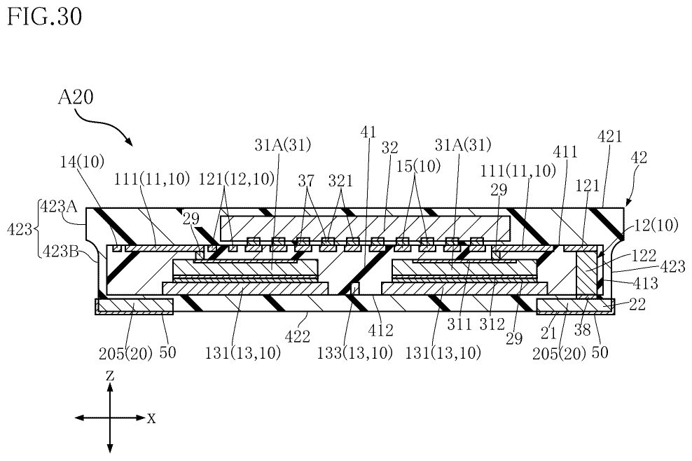

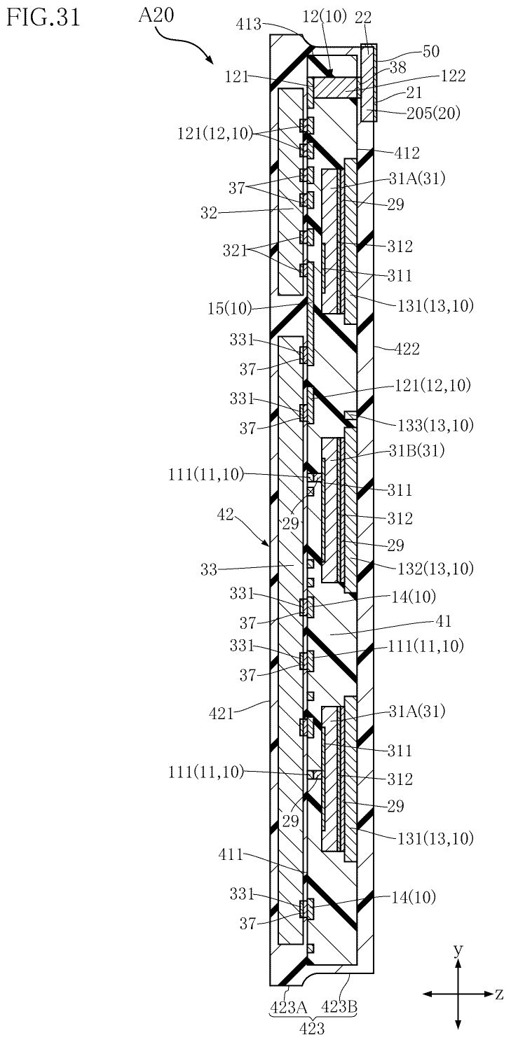

As shown in FIGS. 30 and 31, each terminal 20 has an end surface 22 that is exposed from a second side surface 423 of the second sealing resin 42. Each protective layer 50 covers the end surface 22 of a terminal 20 exposed from a second side surface 423.

As shown in FIG. 29, each terminal 20 protrudes outward from the first sealing resin 41 as viewed in the first direction z.

As shown in FIGS. 29 to 31, each second side surface 423 of the second sealing resin 42 includes a first region 423A and a second region 423B. The first region 423A is connected to the top surface 421. The second region 423B is connected to the bottom surface 422 and the first region 423A. As viewed in the first direction z, the second region 423B overlaps with the top surface 421. As shown in FIG. 29, each second side surface 423 includes a portion located outside the first side surface 413 of the first sealing resin 41 as viewed in the first direction z.

The following describes effects of the semiconductor device A20.

A semiconductor device A20 includes: a wiring layer 10 that includes a first wiring 11 and a second wiring 12; a first semiconductor element 31 that includes a first electrode 311 and a second electrode 312, the first electrode 311 being electrically bonded to the first wiring 11; and a first sealing resin 41 that covers the first semiconductor element 31. The first sealing resin 41 includes a first surface 411 and a second surface 412. The first surface 411 is closer to the first electrode 311 than to the second electrode 312. The second wiring 12 is exposed from each of the first surface 411 and the second surface 412. As viewed in the first direction z, the second wiring 12 is spaced apart from the first semiconductor element 31. This configuration therefore enables the semiconductor device A20 to be more compact. The semiconductor device A20 has a configuration in common with the semiconductor device A10, thereby achieving the same effect as the semiconductor device A10.

In the semiconductor device A20, each terminal 20 is exposed from the second side surface 423 of the second sealing resin 42. The protective layers 50 covers the portions of the respective terminals 20 exposed from the second side surface 423. This configuration facilitates the molten solder to rise along the protective layers 50 in the first direction z during the mounting of the semiconductor device A20 onto a wiring board. This promotes the formation of solder fillets, improving the bonding strength of the semiconductor device A20 to the wiring board. Additionally, externally exposed solder fillets formed during mounting of the semiconductor device A20 to a wiring board allow the bonding condition to be checked easily by visual inspection.

The present disclosure is not limited to the embodiments described above. Various modifications in design may be made freely in the specific structure of each part according to the present disclosure.

The present disclosure includes embodiments described in the following clauses.

### Clause 1.

A semiconductor device comprising:
a wiring layer that includes a first wiring and a second wiring;
a first semiconductor element that includes a first electrode and a second electrode disposed opposite to each other in a first direction, the first electrode being electrically bonded to the first wiring; and
a first sealing resin that covers the first semiconductor element,
wherein the first sealing resin includes a first surface and a second surface facing away from each other in the first direction,
the first surface is closer to the first electrode than to the second electrode,
the second wiring is exposed from each of the first surface and the second surface, and
as viewed in the first direction, the second wiring is spaced apart from the first semiconductor element.

### Clause 2.

The semiconductor device according to Clause 1, wherein the wiring layer is embedded in the first sealing resin, and
the first wiring is exposed from the first surface.

### Clause 3.

The semiconductor device according to Clause 2, wherein the first sealing resin includes a first side surface facing in a direction perpendicular to the first direction, and
the second wiring includes a portion located between the first semiconductor element and the first side surface.

### Clause 4.

The semiconductor device according to Clause 3, wherein the wiring layer includes a third wiring exposed from the second surface, and
the second electrode is electrically bonded to the third wiring.

### Clause 5.

The semiconductor device according to Clause 4, further comprising a second semiconductor element that faces the first surface and is electrically bonded to the second wiring,
wherein as viewed in the first direction, the second semiconductor element overlaps with the first semiconductor element.

### Clause 6.

The semiconductor device according to Clause 5, further comprising a second sealing resin that covers the second semiconductor element,
wherein the wiring layer is in contact with the second sealing resin, and the first surface, the second surface, and the first side surface are each covered with the second sealing resin.

### Clause 7.

The semiconductor device according to Clause 6, wherein the second sealing resin includes a top surface facing a same side as the first surface in the first direction, and
a surface roughness of the second surface is higher than a surface roughness of the top surface.

### Clause 8.

The semiconductor device according to Clause 7, wherein the wiring layer includes a fourth wiring exposed from the first surface,
the first semiconductor element includes a gate electrode on a same side as the first electrode in the first direction, and
the gate electrode is electrically bonded to the fourth wiring.

### Clause 9.

The semiconductor device according to Clause 8, further comprising a third semiconductor element that faces the first surface and is electrically bonded to the fourth wiring,
wherein the third semiconductor element is covered with the second sealing resin, and
as viewed in the first direction, the third semiconductor element overlaps with the first semiconductor element.

### Clause 10.

The semiconductor device according to Clause 9, wherein the wiring layer includes a fifth wiring exposed from the first surface, and
the second semiconductor element and the third semiconductor element are each electrically bonded to the fifth wiring.

### Clause 11.

The semiconductor device according to any one of Clauses 7 to 10, wherein the first wiring includes a wiring section that is exposed from the first surface, and a pillar section that is physically and electrically connected to the wiring section,
with respect to the wiring section, the pillar section is located on a side that the second surface faces in the first direction, and the pillar section is exposed from the second surface.

### Clause 12.

The semiconductor device according to Clause 11, further comprising a plurality of terminals facing the second surface and embedded in the second sealing resin,
wherein each of the plurality of terminals is electrically bonded to one of the second wiring, the third wiring, and the pillar section,
the second sealing resin includes a bottom surface facing away from the top surface in the first direction, and
the plurality of terminals are each exposed from the bottom surface.

### Clause 13.

The semiconductor device according to Clause 12, further comprising:
a first bonding layer that electrically bonds the second wiring to the second semiconductor element; and
a second bonding layer that electrically bonds each of the plurality of terminals to one of the second wiring, the third wiring, and the pillar section,
wherein a melting point of the second bonding layer is different from a melting point of the first bonding layer.

### Clause 14.

The semiconductor device according to Clause 13, further comprising a plurality of protective layers each covering a portion of one of the plurality of terminals that is exposed from the bottom surface, and
wherein the plurality of protective layers are conductors that contain gold.

### Clause 15.

The semiconductor device according to Clause 14, wherein the second sealing resin includes a second side surface connected to the top surface and the bottom surface, and
the plurality of terminals are each exposed from the second side surface.

### Clause 16.

A method for manufacturing a semiconductor device, the method comprising:
forming a first conductive layer;
for a first semiconductor element that includes a first electrode and a second electrode disposed opposite to each other in a first direction, electrically bonding the first electrode to the first conductive layer;
forming a second conductive layer;
electrically bonding the second conductive layer to the second electrode; and
forming a first resin layer that covers the first semiconductor element and in which the first conductive layer and the second conductive layer are embedded,
wherein the electrical bonding of the first electrode to the first conductive layer includes electrically bonding the first electrode to the first conductive layer such that the first semiconductor element is spaced apart from a portion of the first conductive layer as viewed in the first direction,
the forming of the second conductive layer includes depositing the second conductive layer on a substrate by electroplating,
the electrical bonding of the second conductive layer to the second electrode includes inverting the substrate by rotation about a direction perpendicular to the first direction, and
the forming of the first resin layer includes grinding the first resin layer from opposite sides in the first direction to expose the first conductive layer from a first side of the first resin layer in the first direction and to expose the first conductive layer and the second conductive layer from a second side of the first resin layer in the first direction.

### Clause 17.

The method according to Clause 16, further including, after the forming of the first resin layer;
forming a third conductive layer;
electrically bonding a second semiconductor element to a first side of the first conductive layer in the first direction via a first bonding layer; and
electrically bonding a second side of the first conductive layer in the first direction to the third conductive layer via a second bonding layer,
wherein a melting point of the second bonding layer is different from a melting point of the first bonding layer.

### REFERENCE NUMERALS

A10, A20: semiconductor device 10: wiring layer 11: first wiring 111: wiring section 112: pillar section 12: second wiring 121: wiring section 122: pillar section 13: third wiring 131: first pad section 132: second pad section 133: first wiring section 134: second wiring section 14: fourth wiring 15: fifth wiring 16: sixth wiring 161: wiring section 162: pillar section 17: seventh wiring 18: eighth wiring 181: wiring section 182: pillar section 20: terminal 201: first power terminal 202: second electrode terminal 203: third electrode terminal 204: boot terminal 205: control terminal 21: mounting surface 22: end surface 31: first semiconductor element 31A: first element 31B: second element 311: first electrode 312: second electrode 313: gate electrode 32: second semiconductor element 321: electrode 33: third semiconductor element 331: electrode 37: first bonding layer 38: second bonding layer 29: conductive bonding layer 41: first sealing resin 411: first surface 412: second surface 413: first side surface 42: second sealing resin 421: top surface 422: bottom surface 423: second side surface 423A: first region 423B: second region 50: protective layer 811: first substrate 812: second substrate 813: third substrate 82: intermediate layer 83: first conductive layer 84: second conductive layer 85: third conductive layer 86: first resin layer 87: second resin layer z: first direction x: second direction y: third direction

1. A semiconductor device comprising:
a wiring layer that includes a first wiring and a second wiring;
a first semiconductor element that includes a first electrode and a second electrode disposed opposite to each other in a first direction, the first electrode being electrically bonded to the first wiring; and
a first sealing resin that covers the first semiconductor element,
wherein the first sealing resin includes a first surface and a second surface facing away from each other in the first direction,
the first surface is closer to the first electrode than to the second electrode,
the second wiring is exposed from each of the first surface and the second surface, and
as viewed in the first direction, the second wiring is spaced apart from the first semiconductor element.

2. The semiconductor device according to claim 1, wherein the wiring layer is embedded in the first sealing resin, and
the first wiring is exposed from the first surface.

3. The semiconductor device according to claim 2, wherein the first sealing resin includes a first side surface facing in a direction perpendicular to the first direction, and
the second wiring includes a portion located between the first semiconductor element and the first side surface.

4. The semiconductor device according to claim 3, wherein the wiring layer includes a third wiring exposed from the second surface, and
the second electrode is electrically bonded to the third wiring.

5. The semiconductor device according to claim 4, further comprising a second semiconductor element that faces the first surface and is electrically bonded to the second wiring,
wherein as viewed in the first direction, the second semiconductor element overlaps with the first semiconductor element.

6. The semiconductor device according to claim 5, further comprising a second sealing resin that covers the second semiconductor element,
wherein the wiring layer is in contact with the second sealing resin, and
the first surface, the second surface, and the first side surface are each covered with the second sealing resin.

7. The semiconductor device according to claim 6, wherein the second sealing resin includes a top surface facing a same side as the first surface in the first direction, and
a surface roughness of the second surface is higher than a surface roughness of the top surface.

8. The semiconductor device according to claim 7, wherein the wiring layer includes a fourth wiring exposed from the first surface,
the first semiconductor element includes a gate electrode on a same side as the first electrode in the first direction, and
the gate electrode is electrically bonded to the fourth wiring.

9. The semiconductor device according to claim 8, further comprising a third semiconductor element that faces the first surface and is electrically bonded to the fourth wiring,
wherein the third semiconductor element is covered with the second sealing resin, and
as viewed in the first direction, the third semiconductor element overlaps with the first semiconductor element.

10. The semiconductor device according to claim 9, wherein the wiring layer includes a fifth wiring exposed from the first surface, and
the second semiconductor element and the third semiconductor element are each electrically bonded to the fifth wiring.

11. The semiconductor device according to claim 7, wherein the first wiring includes a wiring section that is exposed from the first surface, and a pillar section that is physically and electrically connected to the wiring section,
with respect to the wiring section, the pillar section is located on a side that the second surface faces in the first direction, and
the pillar section is exposed from the second surface.

12. The semiconductor device according to claim 11, further comprising a plurality of terminals facing the second surface and embedded in the second sealing resin,
wherein each of the plurality of terminals is electrically bonded to one of the second wiring, the third wiring, and the pillar section,
the second sealing resin includes a bottom surface facing away from the top surface in the first direction, and
the plurality of terminals are each exposed from the bottom surface.

13. The semiconductor device according to claim 12, further comprising:
a first bonding layer that electrically bonds the second wiring to the second semiconductor element; and
a second bonding layer that electrically bonds each of the plurality of terminals to one of the second wiring, the third wiring, and the pillar section,
wherein a melting point of the second bonding layer is different from a melting point of the first bonding layer.

14. The semiconductor device according to claim 13, further comprising a plurality of protective layers each covering a portion of one of the plurality of terminals that is exposed from the bottom surface, and
wherein the plurality of protective layers are conductors that contain gold.

15. The semiconductor device according to claim 14, wherein the second sealing resin includes a second side surface connected to the top surface and the bottom surface, and
the plurality of terminals are each exposed from the second side surface.

16. A method for manufacturing a semiconductor device, the method comprising:
forming a first conductive layer;
for a first semiconductor element that includes a first electrode and a second electrode disposed opposite to each other in a first direction, electrically bonding the first electrode to the first conductive layer;
forming a second conductive layer;
electrically bonding the second conductive layer to the second electrode; and
forming a first resin layer that covers the first semiconductor element and in which the first conductive layer and the second conductive layer are embedded,
wherein the electrical bonding of the first electrode to the first conductive layer includes electrically bonding the first electrode to the first conductive layer such that the first semiconductor element is spaced apart from a portion of the first conductive layer as viewed in the first direction,
the forming of the second conductive layer includes depositing the second conductive layer on a substrate by electroplating,
the electrical bonding of the second conductive layer to the second electrode includes inverting the substrate by rotation about a direction perpendicular to the first direction, and
the forming of the first resin layer includes grinding the first resin layer from opposite sides in the first direction to expose the first conductive layer from a first side of the first resin layer in the first direction and to expose the first conductive layer and the second conductive layer from a second side of the first resin layer in the first direction.

17. The method according to claim 16, further including, after the forming of the first resin layer;
forming a third conductive layer;
electrically bonding a second semiconductor element to a first side of the first conductive layer in the first direction via a first bonding layer; and
electrically bonding a second side of the first conductive layer in the first direction to the third conductive layer via a second bonding layer,
wherein a melting point of the second bonding layer is different from a melting point of the first bonding layer.
